(19) United States
(12) Patent Application Publication
(10) Pub. No.: US 2018/0128260 A1
(43) Pub. Date: May 10, 2018

(54) AIRFLOW GENERATING DEVICE AND AIRFLOW GENERATING METHOD

(71) Applicants: Inventec (Pudong) Technology Corporation, Shanghai (CN); INVENTEC CORPORATION, TAIPEI CITY (TW)

(72) Inventor: Meng-Lung CHIANG, TAIPEI CITY (TW)

(21) Appl. No.: 15/473,592

(22) Filed: Mar. 29, 2017

(30) Foreign Application Priority Data
Nov. 9, 2016 (CN) 201610983149.5

(51) Int. Cl. F04B 45/047; H01L 41/09; B06B 1/06; H02K 33/16; H01H 50/16; F04B 49/22; F04B 49/06

(52) U.S. Cl. CPC F04B 45/047; H01L 41/09; B06B 1/0607; F04B 49/06; H01H 50/16; F04B 49/22; H02K 33/16

(57) ABSTRACT

An airflow generating device includes a container and an oscillating element. The container has at least one opening. The oscillating element is disposed in the container, separates an inner space of the container into a first space and a second space, in which the first space and the second space are isolated from each other, and the opening is connected to one of the first space and the second space. The oscillating element is configured to oscillate corresponding to do AC magnetic field generated by one or more external power providing coils.

### RELATED ART

This application claims priority to Chinese Application Serial Number 201610983149.5, field Nov. 9, 2016, which is herein incorporated by reference.

### BACKGROUND

### Field of Invention

The present disclosure relates to an airflow device and a method. More particularly, the present disclosure relates to an airflow generating device and an airflow generating method.

### Description of Related Art

With advances in electronic technology, airflow generating devices are widely used in our daily life.

A typical electronic device can dissipate heat thereof by using an airflow generating device, such as a fan. However, the number of different types of applications for the fan is limited due to the noise generated thereby and the lifetime of the motor thereof. In addition, when a wireless device receives a wireless power, power loss would be cause by electronic components, such as rectifiers, and voltage transformer.

Therefore, realization of a low power loss and wireless driving airflow generating device is an important area of research in this field.

### SUMMARY

One aspect of the present disclosure is related to an airflow generating device. In accordance with one embodiment of the present disclosure, the airflow generating device includes a container and an oscillating element. The container has at least one opening. The oscillating element is disposed in the container, separates an inner space of the container into a first space and a second space, in which the first space and the second space are isolated from each other, and the opening is connected to one of the first space and the second space. The oscillating element is configured to oscillate corresponding to an AC magnetic field generated by one or more external power providing coils.

In accordance with one embodiment of the present disclosure the airflow generating device further includes one or more coils configured to generate an AC current and drive the oscillating element to oscillate according to the AC current.

In accordance with one embodiment of the present disclosure, the oscillating element includes a piezoelectric sheet, the piezoelectric sheet is configured to receive the AC current and oscillate the container according to the AC current.

In accordance with one embodiment of the present disclosure, the oscillating element is a magnetic oscillating element, the AC magnetic field applies a magnetic force to the magnetic oscillating element, so as to make the magnetic oscillating element oscillate according to the magnetic force.

In accordance with one embodiment of the present disclosure, the at least one opening includes a first opening and a second opening. The airflow generating device further includes a first air switch configured to open or close the first opening corresponding to the AC magnetic field and a second air switch configured to open or close the second opening corresponding to the AC magnetic field. Under a condition that the first air switch closes the first opening, the second air switch opens the second opening, and under a condition that the second air switch closes the second opening, the first air switch opens the first opening.

In accordance with one embodiment of the present disclosure wherein the first air switch includes a first magnetic element, and the first magnetic element motions corresponding to the AC magnetic field to open or close the first opening.

In accordance with one embodiment of the present disclosure, the airflow generating device further includes one or more switching coils configured to generate at least one switching current corresponding to the AC magnetic field and drive the first air switch open or close the first opening by using the switching current.

In accordance with one embodiment of the present disclosure, the airflow generating device further includes a switching component electrically connected between the one or more switching coils, the first air switch, and the second air switch. When the switching component is in a first switching state, when the oscillating element is changing a shape thereof toward a first direction corresponding to the AC magnetic field, the one or more switching coils generate a first switching current corresponding to the AC magnetic field, so as to make the first air switch close the first opening according to the first switching current, and make the second air switch open the second opening according to the first switching current. When the oscillating element is changing the shape thereof toward a second direction corresponding to the AC magnetic field, the one or more switching coils generate a second switching current corresponding to the AC magnetic field, so as to make the first air switch open the first opening according to the second switching current, and make the second air switch close the second opening according to the second switching current.

In accordance with one embodiment of the present disclosure, When the switching component is in a second switching state, when the oscillating element is changing the shape thereof toward the first direction corresponding to the AC magnetic field, the one or more switching coils generate the first switching current corresponding to the AC magnetic field, so as to make the first air switch open the first opening according to the first switching current, and make the second air switch close the second opening according to the first switching current. When the oscillating element is changing the shape thereof toward the second direction corresponding to the AC magnetic field, the one or more switching coils generate the second switching current corresponding to the AC magnetic field, so as to make the first air switch close the first opening according to the second switching current, and make the second air switch open the second opening according to the second switching current.

Another aspect of the present disclosure is related to an airflow generating method. In accordance with one embodiment of the present disclosure, the airflow generating method includes sensing, through a magnetic element or one or more coils, an AC magnetic field generated by one or more external power providing coils; and oscillating, through an oscillating element disposed in a container, corresponding to the AC magnetic field. The oscillating element separates an inner space of the container into a first space and a second space, the first space and the second space are isolated from each other, and at least one opening of the container is connected to one of the first space and the second space.

Through utilizing one embodiment described above, a wireless driving airflow generating device can be realized.

### BRIEF DESCRIPTION OF THE DRAWINGS

FIG. 1 is a schematic diagram of an airflow generating device according to one embodiment of the present disclosure.

FIG. 2 is a schematic diagram of an airflow generating device according to another embodiment of the present disclosure.

FIG. 3 is a circuit diagram of coils, a first air switch, and a second air switch according to one embodiment of the present disclosure.

FIG. 4A illustrates an operative example of the airflow generating device is according to one embodiment of the present disclosure.

FIG. 4B illustrates an operative example of the airflow generating device is according to one embodiment of the present disclosure.

FIG. 4C illustrates an operative example of the airflow generating device is according to one embodiment of the present disclosure.

FIG. 4D illustrates an operative example of the airflow generating device is according to one embodiment of the present disclosure.

FIG. 5 is a circuit diagram of coils, a first air switch, and a second air switch according to another embodiment of the present disclosure.

FIG. 6A illustrates an operative example of the airflow generating device is according to another embodiment of the present disclosure.

FIG. 6B illustrates an operative example of the airflow generating device is according to another embodiment of the present disclosure.

FIG. 6C illustrates an operative example of the airflow generating device is according to another embodiment of the present disclosure.

FIG. 6D illustrates an operative example of the airflow generating device is according to another embodiment of the present disclosure.

FIG. 7 is a schematic diagram of an airflow generating device according to another embodiment of the present disclosure.

FIG. 8 is a schematic diagram of an airflow generating device according to another embodiment of the present disclosure.

FIG. 9 is a schematic diagram of an airflow generating device according to another embodiment of the present disclosure.

FIG. 10 is a schematic diagram of an airflow generating device according to another embodiment of the present disclosure.

FIG. 11 is a flowchart of an airflow generating method according to one embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the embodiments.

It will be understood that in the description herein and throughout the claims that follow, when an element is referred to as being “connected” or “electrically connected” to another element, it can be directly connected to the other element or intervening elements may be present. In contrast, when an element is referred to as being “directly connected” to another element, there are no intervening elements present. Moreover, “electrically connect” or “connect” can further refer to the interoperation or interaction between two or more elements.

It will be understood that, in the description herein and throughout the claims that follow, the terms “comprise” or “comprising,” “include” or “including,” “have” or “having,” “contain” or “containing” and the like used herein are to be understood to be open-ended, i.e., to mean including but not limited to.

It will be understood that, in the description herein and throughout the claims that follow, the phrase “and/or” includes any and all combinations of one or more of the associated listed items.

It will be understood that, in the description herein and throughout, the claims that follow, words indicating direction used in the description of the following embodiments, such as “above,” “below,” “left,” “right,” “front” and “back,” are directions as they relate to the accompanying drawings. Therefore, such words indicating direction are used for illustration and do not limit the present disclosure.

It will be understood that, in the description herein and throughout the claims that follow, the term “substantially” is used in association with values that may vary slightly, in which such minor errors do not change the properties and the characteristics relevant to the values.

It will be understood that, in the description herein and throughout the claims that follow, unless otherwise defined, all terms (including technical and scientific terms) have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Any element in a claim that does not explicitly state “means for” performing a specified function, or “step for” performing a specific function, is not to be interpreted as a “means” or “step” clause as specified in 35 U.S.C. §112(f). In particular, the use of “step of” in the claims herein is not intended to invoke the provisions of 35 U.S.C. §112(f).

One aspect of the present disclosure relates to an airflow generating device. In the paragraphs below, a heat dissipation device in an electronic device will be taken as an example to describe details of the airflow generating device. However, another airflow generating device is within the contemplated scope of the present disclosure.

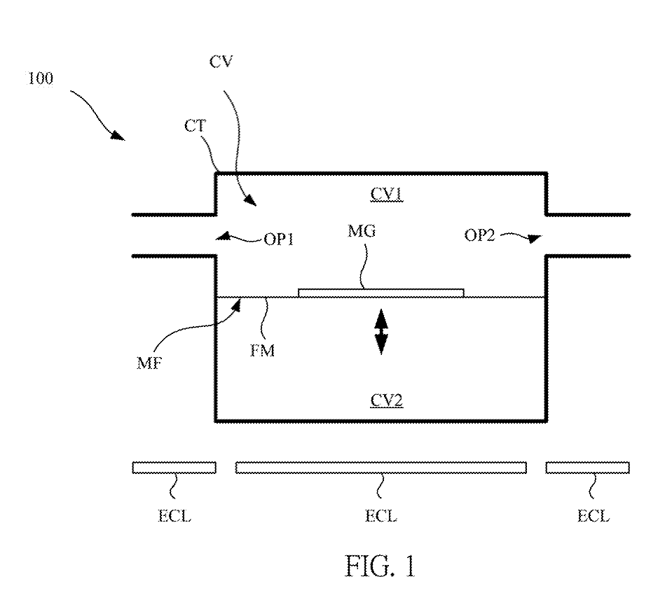

FIG. 1 is a schematic diagram of an airflow generating device 100 according to one embodiment of the present disclosure. In this embodiment, the airflow generating device 100 includes a container CT and an oscillating element MF.

In this embodiment, the container CT has a first opening OP1 and a second opening OP2. In one embodiment the first opening OP1 is disposed at one side (e.g. a left side) of the container CT, and the second opening OP2 is disposed at an opposite side (e.g., a right side) of the container CT. It should be noted that another amount of the openings of the container CT (e.g., one or more than two openings) is within the contemplated scope of the present disclosure. Moreover, in alternative embodiments, different openings can be located at two adjacent sides of the container CT or located at a same side of the container CT. It should be noted that, in this embodiment, a cubic container CT is taken as a descriptive example, but the container CT with a different shape is within the contemplated scope of the present disclosure.

In this embodiment, the oscillating element MF is disposed in the container CT. In one embodiment, the oscillating element MF separates the space CV inside the container CT into a first space CV1 and a second space CV2, in which the first space CV1 and the second space CV2 are substantially isolated from each other airtightly. In one embodiment, the first opening OP1 and the second opening OP2 are connected to the first space CV1. In an alternative embodiment, the first opening OP1 and the second opening OP2 may also be connected to the second space CV2.

In one embodiment, the oscillating element MF is configured to oscillate corresponding to an AC magnetic field generated by one o more external power providing coils ECL. In one embodiment, the one or more external power providing coils ECL may be power transmitting component of an external wireless power providing device. In one embodiment, the external wireless power providing device may provide one or more power providing AC currents to the one or more external power providing coils ECL, so as to make the one or more external power providing coils ECL generate the AC magnetic field. For example, in a first period, the N pole of the magnetic field generated by the one or more external power providing coils ECL is directed toward the airflow generating device 100 (e.g. directed upward), and the S pole of the magnetic field is directed opposite from the generating device 100 (e.g., directed downward). In a second period, the S pole of the magnetic field generated by the one or more external power providing coils ECL is directed toward the airflow generating device 100 (e.g., directed upward), and the N pole of the magnetic field is directed opposite from the generating device 100 (e.g., directed downward). The magnetic direction of the magnetic field generated by the one or more external power providing coils ECL is changed alternatively. In one embodiment, magnetic directions of AC magnetic fields generated by multiple external power providing coils ECL can be identical to each other (e.g., in phase) or different from each other (e.g., out of phase) on a basis of actual requirements.

In one embodiment, the oscillating element MF can be a magnetic oscillating element. The one or more external power providing coils ECL may apply a magnetic force to this magnetic oscillating element, so as to make this magnetic oscillating element oscillate according to the magnetic force.

In one embodiment, the oscillating element MF includes an oscillating film FM and a magnetic element MG (e.g., a magnet or an electromagnet). The oscillating film FM is disposed in the container CT, used to substantially separate the first space CV1 and the second space CV2. The magnetic element MG is disposed on the oscillating film FM. In one embodiment, the one or more external power providing coils ECL can apply magnetic force to the magnetic element MG, so as to make the magnetic element MG motion according to the magnetic force, to make the oscillating film FM oscillate accordingly. It should be noted that, in one embodiment, there may be multiple magnetic elements MG disposed on the oscillating film FM, and the present disclosure is not limited by the embodiment described above. Additionally, in some alternative embodiments, the oscillating film FM can be realized by using a magnetic film, and the present disclosure is not limited by the embodiment described above.

For example, under a condition that the N pole of the oscillating element MF is facing toward the one ore external power providing coils ECL (e.g., facing downward), and the S pole of the oscillating element MF is facing opposite to the one or more external power providing coils ECL (e.g., facing upward), during a period that the N pole of the magnetic field generated by the one or more external power providing coils ECL is directed toward the oscillating element MF (e.g., directed upward), and the S pole of the magnetic field is directed opposite to oscillating element MF (e.g., directed downward), a repulsive force is generated between the one or more external power providing coils ECL and the oscillating element MF, so as to make the oscillating element MF be changing its shape toward a direction opposite to the one or more external pm e r providing coils ECL (e.g., changing the shape upward). In this period, the first spacing CV1 is being compressed and the second spacing CV2 is being expanded, so that the airflow generating device 100 blows air by using the first opening OP1 and the second opening OP2.

During a period that the S pole of the magnetic field generated by the one or more external power providing coils ECL is directed toward the oscillating element MF (e.g., directed upward), and the N pole of the magnetic field is directed opposite to oscillating element MF (e.g., directed downward), an attractive force is generated between the one or more external power providing coils ECL and the oscillating element MF, so as to make the oscillating element MF be changing its shape toward the one or more external power providing coils ECL (e.g., changing the shape downward). In this period, the first spacing CV1 is being expanded and the second spacing CV2 is being compressed, so that the airflow generating device 100 sucks air by using the first opening OP1 and the second opening OP2.

With such a configuration, a wireless driving airflow generating device 100 can be realized. In addition, since the airflow generating device 100 can receive the power from the one or more external power providing coils ECL without using electronic elements (e.g., rectifiers and transformers), so that power loss can be decreased.

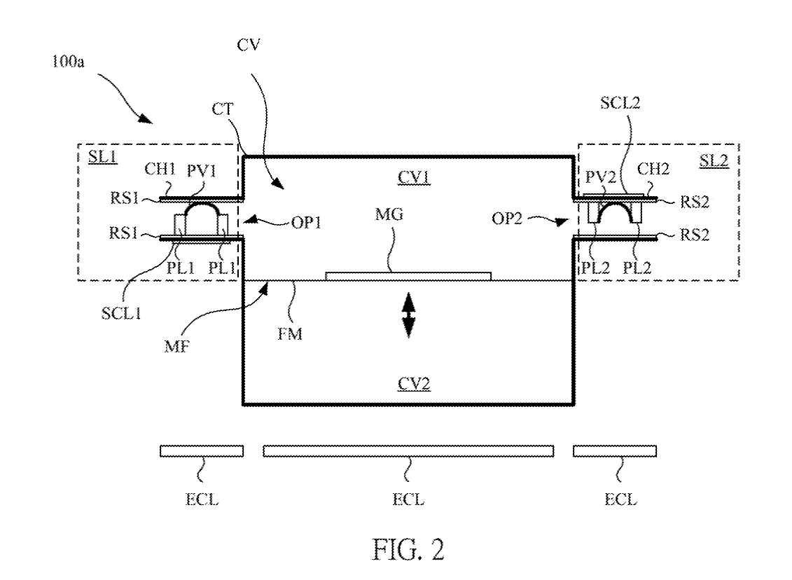

FIG. 2 is a schematic diagram of an airflow generating device 100a according to another embodiment of the present disclosure. In this embodiment, the airflow generating device 100a includes a container CT, a first air switch SL1, a second air switch SL2, an oscillating element MF, and switching coils CL1, SCL2. In this embodiment, the container CT and the oscillating element MF of the airflow generating device 100a are substantially identical to the container CT and the oscillating element MF of the airflow generating device 100. Thus, a description of many aspects in this regard will not be repeated.

In one embodiment, the first air switch SL1 is disposed at the first opening OP1, configured to open or close the first opening OP1. The second air switch SL2 is disposed at the second opening OP2, configured to open or close the second opening OP2.

In one embodiment, the switching coils CL1, SCL2 are disposed at locations that can easily sense the AC magnetic field generated by the one or more external power providing coils ECL. In one embodiment, the switching coils SCL1, SCL2 are disposed on the container CT. In one embodiment, the switching coil SCL1 is disposed at one side (e.g., the bottom side) of the first air switch SL1, and the switching coil SCL2 is disposed at one side (e.g., the top side) of the second air switch SL2. In one embodiment, the switching coils SCL1, SCL2 may be separately realized by one or more of a planar coil, a coil with a solid form, or a PCB coil, but another realization manner is within the contemplated scope of the present disclosure. it should be noted that two switching coils SCL1, SCL2 are taken as an example in this embodiment, but another amount of the switching coils (e.g., one or more than two) is within the contemplated scope of the present disclosure. Moreover, in this embodiment, the switching coils SCL1 SCL2 are disposed outside the first air switch SL1 and the second air switch SL2. However, the switching coils SCL1, SCL2 may also be separately disposed inside and/or outside the first air switch SL1, the second air switch SL2, and/or the container CT. Furthermore, the switching coils SCL1, SCL2 can be disposed at any appropriated locations of the airflow generating device 100a or apart from the airflow generating device 100a on a basis of actual requirements, and the present disclosure is not limited by this embodiment.

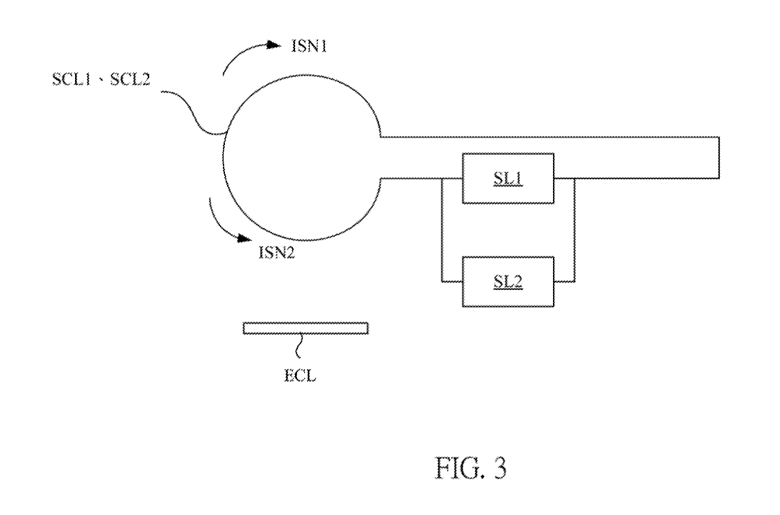

Reference is also made to FIG. 3. FIG. 3 is circuit diagram of the switching coils SCL1, SCL2, the first air switch SL1, and the second air switch SL2 according to one embodiment of the present disclosure. In one embodiment, when the one or more external power providing coils ECL generate the AC magnetic field, the switching coils SCL1, SCL2 are configured to generate an induced magnetic field and an induced AC current corresponding to the AC magnetic field generated by the one or more external power providing coils ECL. In this embodiment, this induced AC current may include switching currents ISN1, ISN2 with different flowing directions. The first air switch SL1 and the second air switch SL2 respectively opens or closes the first opening OP1 and the second opening OP2 according to this induced AC current (i.e., the switching currents ISN1 ISN2).

For example, when the oscillating element MF is changing the shape thereof toward a first direction (e.g., toward an up direction), the switching coils SCL1, SCL2 generate the first switching current ISN1, so as to make the first air switch SL1 close the first opening OP1 according to the first switching current ISN1, and make the second air switch SL2 open the second opening OP2 according to the first switching current ISN1. In this period, the first spacing CV1 is being compressed and the second spacing CV2 is being expanded, so that the airflow generating device 100a blows air by using the second opening OP2.

When the oscillating element MP is changing the shape thereof toward a second direction (e.g., toward an down direction), the switching coils SCL1, SCL2 generate the second switching current ISN1, so as to make the first air switch SL1 open the first opening OP1 according to the second switching current ISN2, and make the second air switch SL2 close the second opening OP2 according to the second switching current ISN2. In this period, the first spacing CV1 is being expanded and the second spacing CV2 is being compressed, so that the airflow generating device 100a blows air by using the second opening OP2.

With such a configuration, an airflow generating device can be realized. The openings of the airflow generating device can be opened or closed corresponding to the oscillation of the magnetic oscillating element, so that an airflow with certain direction (e.g., from the first opening OP1 to the second opening) can be generated.

In one embodiment, the first opening OP1 and the second opening OP2 are not closed concurrently. When the second opening OP2 is closed, the first opening OP1 is opened, and when the first opening OP1 is closed, the second opening OP2 is opened.

In one embodiment, the first air switch SL1 open or close the first opening OP1 corresponding to the first space CV1 is being compressed or expanded. In one embodiment, the second air switch SL2 open or close the second opening OP2 corresponding to the first space CV1 is being compressed or expanded.

In one embodiment, the first air switch SL1 includes a piezoelectric sheet PV1, pillars PL1, and a channel CH1. In one embodiment, the piezoelectric sheet PV1 and the pillars PL1 are disposed within the channel CH1. In one embodiment, the pillars PL1 are disposed at the bottom side of the channel CH1. Two ends of the piezoelectric sheet PV1 are separately disposed at the pillars PL1. In one embodiment, the piezoelectric sheet PV1 bends toward different directions according to the switching currents ISN1, ISN2, so as to open or close the first opening OP1. For example, the piezoelectric sheet PV1 may bend upward according to the first switching current ISN1 to close the first opening OP1, and the piezoelectric sheet PV1 may bend downward according to the second switching current. ISN2 to open the first opening OP1. It should be noted that the pillars PL1 can be disposed at the top side or the bottom side of the channel CH1 on a basis of actual requirements, and the present disclosure is not limited by this embodiment.

In on embodiment, the first air switch SL1 further includes a resilience cushion RS1 disposed between the channel CH1 end the piezoelectric sheet PV1. In one embodiment, the resilience cushion RS1 can be disposed at the top side and/or the bottom side of the channel CH1. Under a condition that the piezoelectric sheet PV1 open or close the first opening OP1, the piezoelectric sheet PV1 is against the channel CH1 with the resilience cushion RS1 intervened, so as to avoid abrasions of the piezoelectric sheet PV1 and the channel CH1.

In one embodiment, the second air switch SL2 includes a piezoelectric sheet PV2, pillars PL2, and a channel CH2. In one embodiment, the piezoelectric sheet PV2 and the pillars PL2 are disposed within the channel CH2. In one embodiment, the pillars PL2 are disposed at the top side of the channel CH2. Two ends of the piezoelectric sheet PV2 are separately disposed at the pillars PL2. In one embodiment, the piezoelectric sheet PV2 bends toward different directions according to the switching currents ISN1, ISN2, so as to open or close the second opening OP2. For example, the piezoelectric sheet PV2 may bend upward according to the first switching current ISN1 to open the second opening OP2, and the piezoelectric sheet PV2 may bend downward according to the second switching current ISN2 to close the second opening OP2. It should be noted that the pillars PL2 can be disposed at the top side or the bottom side of the channel CH2 on a basis of actual requirements, and the present disclosure is not limited by this embodiment.

In one embodiment, the second air switch SL2 further includes a resilience cushion RS2 disposed between the channel CH2 and the piezoelectric sheet PV2. In one embodiment, the resilience cushion RS2 can be disposed at the top side and/or the bottom side of the channel CH2. Under a condition that the piezoelectric sheet PV2 open or close the second opening OP2, the piezoelectric sheet PV2 is against the channel CH2 with the resilience cushion RS2 intervened, so as to avoid abrasions of the piezoelectric sheet PV2 and the channel CH2.

To allow the disclosure to be more fully understood, an operative example is described in the paragraphs below, but the present disclosure is not limited to the example below.

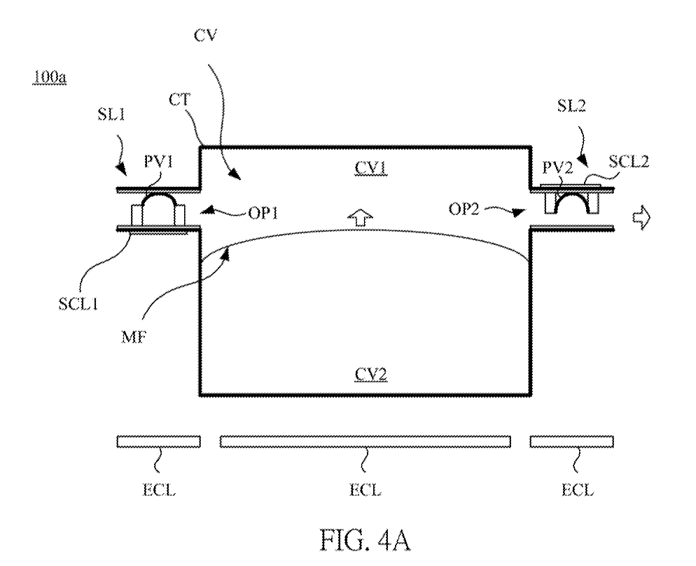

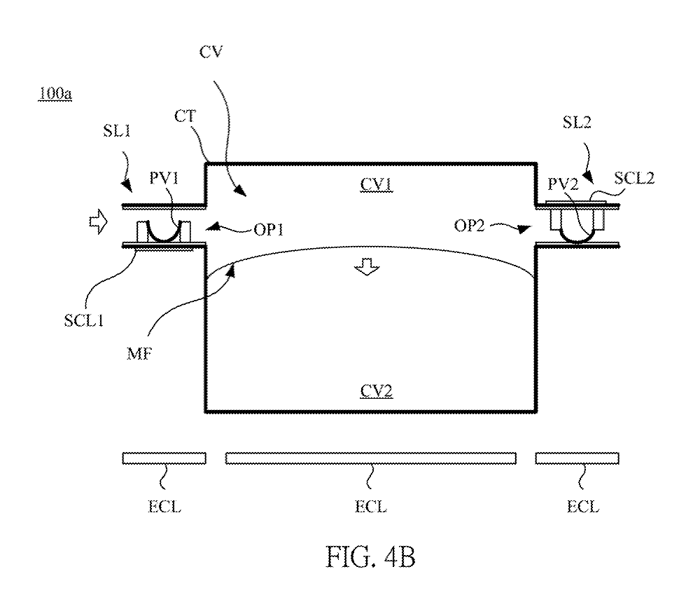

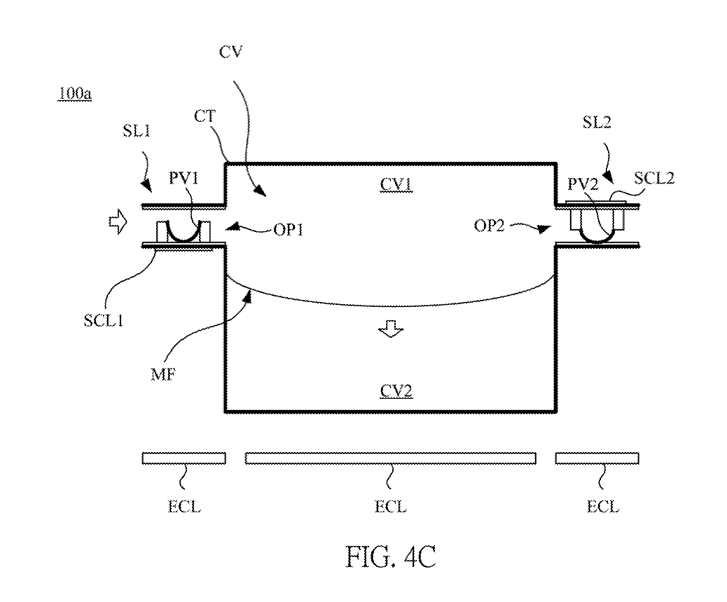

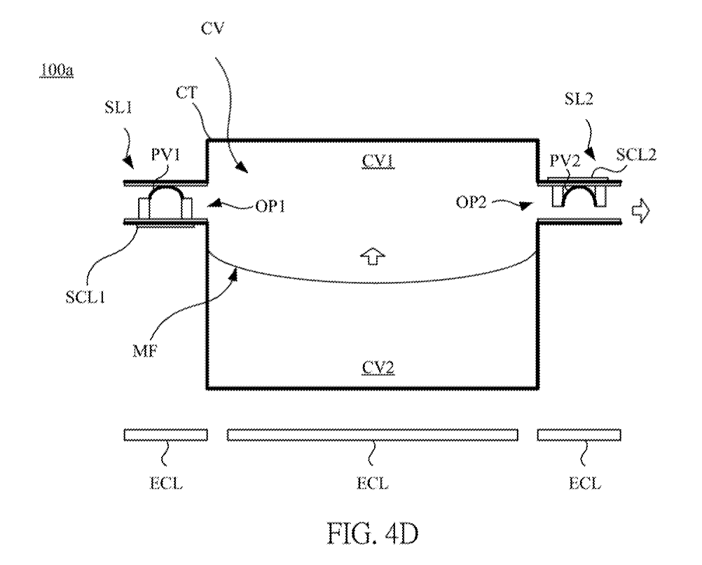

Reference is made to FIG. 4A. When the oscillating element MF is changing the shape thereof upward, the switching coils SCL1, SCL2 generate the first switching current ISN1. The piezoelectric sheet PV1 bends upward according to the first switching current ISN1 to close the first opening OP1. The piezoelectric sheet PV2 bends upward according to the first switching current ISN1 to open the second opening OP2. During this period, since the first space CV1 is being compressed, the airflow generating device 100a blows air by using the opened second opening OP2.

Reference is made to FIG. 4B. When the oscillating element MF is changing the shape thereof downward, the witching coils SCL1 SCL2 generate the second switching current ISN2. The piezoelectric sheet PV1 bends downward according to the second switching current ISN2 to open the first opening OP1. The piezoelectric sheet PV2 bends downward according to the second switching current ISN2 to close the second opening OP2. During this period since the first space CV1 is being expanded, the airflow generating device 100 sucks air by using the opened first opening OP1.

Reference is made to FIG. 4C. When the oscillating element MF is changing the shape thereof downward, the switching coils SCL1, SCL2 generate the second switching current ISN2. The piezoelectric sheet PV1 bends downward according to the second switching current ISN2 to open the first opening OP1. The piezoelectric sheet PV2 bends downward according to the second switching current ISN2 to close the second opening OP2. During this period since the first space CV1 is being expanded, the airflow generating device 100 sucks air by using the opened first opening OP1.

Reference is made to FIG. 4D. When the oscillating element MF is changing the shape thereof upward, the switching coils SCL1, SCL2 generate the first switching current ISN1. The piezoelectric sheet PV1 bends upward according to the first switching current ISN1 to close the first opening OP1. The piezoelectric sheet PV2 bends upward according to the first switching current ISN1 to open the second opening OP2. During this period, since the first space CV1 is being compressed, the airflow generating device 100a blows air by using the opened second opening OP2.

Through the operations described above, the airflow generating device 100a can suck air by using the first opening OP1 and blow air by using the opened second opening OP2. In such a manner, airflow with a fixed direction can be generated and it can avoid hot air to be sucked back into the airflow generating device 100 to decrease the heat dissipation efficiency.

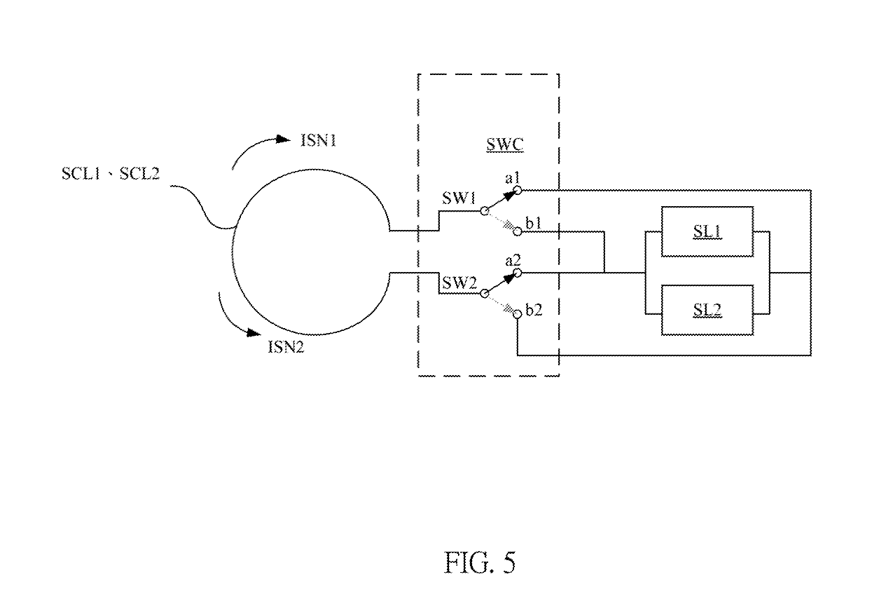

Reference is made to FIG. 5. In another embodiment of the present disclosure in addition to the container CT the first air switch SL1, the second air switch SL2, the oscillating element MF, and the switching coils SCL1, SCL2 described above, the airflow generating device 100a further includes a switching element SWC.

In this embodiment, the switching element SWC is electrically connected between the switching coils SCL1, SCL2, the first air switch SL1 and the second air switch SL2, configured to selectively change current paths of the switching currents ISN1, ISN2, In one embodiment the switching element SWC is configured to selectively change directions of the switching currents ISN1, ISN2 passing through the first air switch SL1 and the second air switch SL2.

In one embodiment, the switching element SWC may include switch SW1 and switch SW2. The switch SW1 is electrically connected between the switching coils SCL1, SCL2 and the first air switch SL1. The switch SW2 is electrically connected between the switching coils SCL1, SCL2 and the second air switch SL2. Under a condition that the switching element SWC is in a first switching state, the switch SW1 connects point a1, and the switch SW2 connects point a2. At this time, the current directions of the switching currents ISN1, ISN2 passing through the first air switch SL1 and the second air switch SL2 are identical to the current directions of the switching currents ISN1, ISN2 passing through the first air switch SL1 and the second air switch SL2 as shown in FIG. 3.

That is, when the oscillating element MF is changing the shape thereof toward a first direction (e.g., a up direction), the switching coils SCL1, SCL2 generate the first switching current ISN1, so as to make the first air switch SL1 close the first opening OP1 according to the first switching current ISN1, and make the second air switch SL2 open the second opening OP2 according to the first switching current ISN1. When the oscillating element MF is changing the shape thereof toward a second direction (e.g., a down direction), the switching coils SCL1, SCL2 generate the second switching current ISN2, so as to make the first air switch SL1 open the first opening OP1 according to the second switching current ISN2, and make the second air switch SL2 close the second opening OP2 according to the second switching current ISN2.

Under a condition that the switching element SWC is in a second switching state, the switch SW1 connects point b1, and the switch SW2 connects point b2. At this time, the current directions of the switching currents ISN1, ISN2 passing through the first air switch SL1 and the second air switch SL2 are opposite to the current directions of the switching currents ISN1, ISN2 passing through the first air switch SL1 and the second air switch SL2 as shown in FIG. 3.

That is, when the oscillating element MF is hanging the shape thereof toward a first direction (e.g., a up direction), the switching coils SCL1 SCL2 generate the first switching current ISN1, so as to make the first air switch SL1 open the first opening OP1 according to the first switching current ISN1, and make the second air switch SL2 close the second opening OP2 according to the first switching current ISN1. When the oscillating element MF is changing the shape thereof toward a second direction (e.g., a down direction), the switching coils SCL1, SCL2 generate the second switching current ISN2, so as to make the first air switch SL1 close the first opening OP1 according to the second switching current ISN2, and make the second air switch SL2 open the second opening OP2 according to the second switching current ISN2.

To allow the disclosure to be or fully understood an operative example relating to operations of the airflow generating device 100a under the second switching state is described in the paragraphs below (the operations of the airflow generating device 100a under the first switching state can be ascertained with reference to the paragraphs corresponding to FIG. 4A-FIG. 4D), but the present disclosure is not limited to the example below.

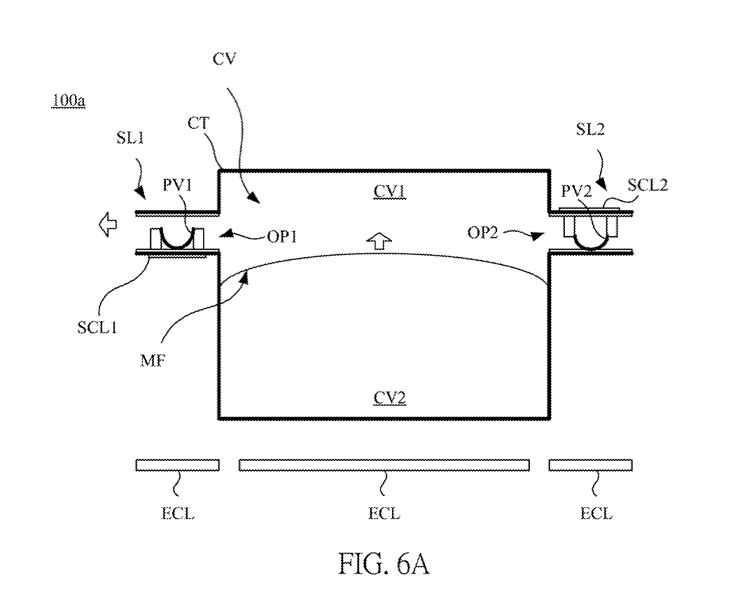

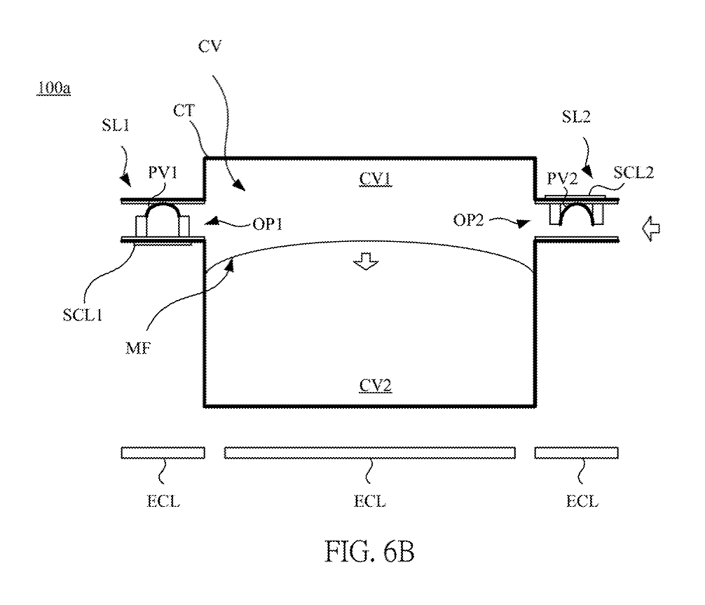

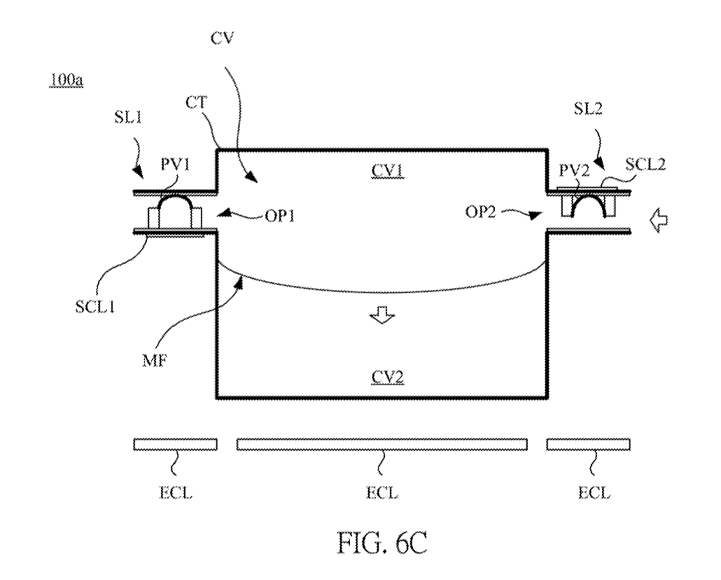

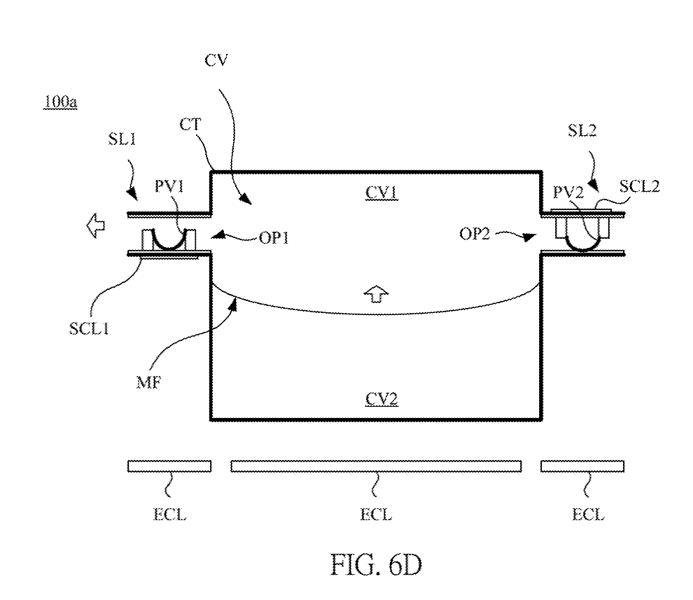

Reference is made to FIG. 6A. When the oscillating element MF is changing the shape thereof upward, the switching coils SCL1, SCL2 generate the first switching current ISN1. The piezoelectric sheet PV1 bends downward according to the first switching current ISN1 to open the first opening OP1. The piezoelectric sheet PV2 bends downward according to the first switching current ISN1 to close the second opening OP2. During this period, since the first space CV1 is being compressed, the airflow generating device 100a blows air by using the opened first opening OP1.

Reference is made to FIG. 6B. When the oscillating element MF is changing the shape thereof downward the switching coils SCL1 SCL2 generate the second switching current ISN2. The piezoelectric sheet PV1 bends upward according to the second switching current ISN2 to close the first opening OP1. The piezoelectric sheet PV2 bends upward according to the second switching current ISN2 to open the second opening OP2. During, this period, since the first space CV1 is being expanded, the airflow generating device 100a sucks air by using the opened second opening OP2.

Reference is made to FIG. 6C. When the oscillating element MF is changing the shape thereof downward, the switching coils SCL1, SCL2 generate the second switching current ISN2. The piezoelectric sheet PV1 bends upward according to the second switching current ISN2 to close the first opening OP1. The piezoelectric sheet PV2 bends upward according to the second switching current ISN2 to open the second opening OP2. During this period, since the first space CV1 is being expanded, the airflow generating device 100a sucks air by using the opened second opening OP2.

Reference is made to FIG. 6D, When the oscillating element MF is changing the shape thereof upward, the switching coils SCL1, SCL2 generate the first switching current ISN1 The piezoelectric sheet PV1 bends downward according to the first switching current ISN1 to open the first opening OP1. The piezoelectric sheet PV2 bends downward according to the first switching current ISN1 to close the second opening OP2. During this period, since the first space CVI is being compressed, the airflow generating device 100a blows air by using the opened first opening OP1.

Through the operations described above, the airflow generating device 100a can blow air by using the first opening OP1 and suck air by using the opened second opening OP2. In such a manner, the airflow generating device 100a can have an expanded number of applications.

In one embodiment, the airflow generating device 100a can be disposed in an electronic device 10. In one embodiment, the electronic device 10 further includes a controller CTL and a gravity sensor GSN. The controller CTL electrically connected to the airflow generating device 100a and the gravity sensor GS. The controller CTL can be realized by, for example, a central processor (CPU), a microprocessor, a programmable logic device (PLD), a field-programmable gate array (FPGA) or another suitable processing component.

In one embodiment, the controller CTL can control the switching element SWC to switch to the first switching state or the second switching state described above according to a gravity, direction GD sensed by the gravity sensor GSN. That is, the switching element SWC changes current paths of the first switching current ISN1 and the second switching current ISN2 according to the gravity direction GD sensed by the gravity sensor GSN, and changes current directions of the first switching current ISN1 and the second switching current ISN2 passing through the first air switch SL1 and the second air switch SL2 according to the gravity direction GD sensed by the gravity sensor GSN. In one embodiment, the controller CTL can control the switching element SWC to switch to the first switching state or the second switching state described above according to the gravity direction GD sensed by the gravity sensor GSN, so as to make the airflow generating device 100a generate airflow with a direction substantially opposite to the gravity direction GD to facilitate heat dissipation of the electronic device 10.

For example, in one embodiment, when the electronic device 10 is upright, the facing direction of the first opening OP1 (e.g., facing the down direction) is substantially identical to the gravity direction GD, and the facing direction of the second opening OP2 (e.g., facing the up direction) is substantially opposite to the gravity direction GD. The controller CTL can control the switching element SWC to switch to the first switching state described above according to the gravity direction GD sensed by the gravity sensor GSN, so that the airflow generating device 100a sucks air by using the first opening OP1 and blows air by using the second opening OP2, so as to generate airflow with a direction substantially opposite to the gravity direction GD.

For another example, in one embodiment, when the electronic device 10 is disposed upside down, the facing direction of the first opening OP1 (e.g., facing the up direction) is substantially opposite to the gravity direction GD, and the facing direction of the second opening OP2 (e.g., facing the down direction) is substantially identical to the gravity direction GD. The controller CTL can control the switching element SWC to switch to the second switching state described above according to the gravity direction GD sensed by the gravity sensor GSN, so that the airflow generating device 100a sucks air by using the second opening OP2, and blows air by using the first opening OP1, so as to generate airflow with a direction substantially opposite to the gravity direction GD.

In another embodiment, the airflow generating device 100a can be disposed in an electronic device 20. In one embodiment, the electronic device 20 further includes a controller CTL, electronic components CM1, CM2, and thermal sensors TSN1, TSN2. In one embodiment, the thermal sensors TSN1, TSN2 are respectively disposed adjacent to the electronic components CM1, CM2, and respectively configured to sensing the temperatures of the electronic components CM1, CM2. The controller CTL is electrically connected to the airflow generating device 100a and the thermal sensors TSN1, TSN2. The controller CTL can be realized by, for example, a central processor (CPU), a microprocessor, a programmable logic device (PLD), a field-programmable gate array (FPGA) or another suitable processing component.

In one embodiment, the controller CTL can control the switching element SWC to switch to the first switching state or the second switching state described above according to the temperatures sensed by the thermal sensors TSN1, TSN2. That is, the switching element SWC changes current paths of the first switching current ISN1 and the second switching current ISN2 according to the temperatures sensed by the thermal sensors TSN1, TSN2, and changes current directions of the first switching current ISN1 and the second switching current ISN2 passing through the first air switch SL1 and the second air switch SL2 according to the temperatures sensed by the thermal sensors TSN1, TSN2. In one embodiment, the controller CTL can control the switching element SWC to switch to the first switching state or the second switching state described above according to the temperatures sensed by the thermal sensors TSN1, TSN2, so as to make the airflow generating device 100a generate airflow with a direction toward one of the electronic components CM1, CM2 having a higher temperature, to facilitate heat dissipation of one of the electronic components CM1, CM2 having a higher temperature.

For example, in one embodiment the first opening OP1 is facing toward the electronic component CM1, and the second opening OP2 is facing toward the electronic component CM2. The thermal sensor TSN1 is disposed adjacent to the electronic component CM1, configured to sense the temperature of the electronic component CM1. The thermal sensor TSN2 is disposed adjacent to the electronic component CM2, configured to sense the temperature of the electronic component CM2. Under a condition that the temperature sensed by the thermal sensor TSN1 is lower than the temperature sensed by the thermal sensor TSN2, the controller CTL can correspondingly control the switching element SWC to switch to the first switching state described above, so that the airflow generating device 100a sucks air by using the first opening OP1, and blows air by using the second opening OP2, so as to generate airflow blowing to the electronic component CM2. On the other hand, under a condition that the temperature sensed by the thermal sensor TSN1 is greater than the temperature sensed by the thermal sensor TSN2, the controller CTL can correspondingly control the switching element SWC to switch to the second switching state described above, so that the airflow generating device 100a sucks air by using the second opening OP2, and blows air by using the first opening OP1, so as to generate airflow blowing to the electronic component CM1.

For another example, in one embodiment, the first opening OP1 is facing toward the electronic component CM1, and the second opening OP2 is facing toward the electronic component CM2. The thermal sensor TSN1 is disposed adjacent to the electronic component CM1, configured to sense the temperature of the electronic component CM1. The thermal sensor TSN2 is disposed adjacent to the electronic component CM2, configured to sense the temperature of the electronic component CM2. In one embodiment, under a condition that the temperature sensed by the thermal sensor TSN2 is greater than a predetermined threshold, the controller CTL can correspondingly control the switching element SWC to switch to the first switching state described above, so that the airflow generating device 100a sucks air by using the first opening OP1, and blows air by using the second opening OP2, so as to generate airflow blowing to the electronic component CM2. In one embodiment, under a condition that the temperature sensed by the thermal sensor TSN1 is greater than a predetermined threshold, the controller CTL can correspondingly control the switching element SWC to switch to the second switching state described above, so that the airflow generating device 100a sucks air by using the second opening OP2, and blows air by using the first opening OP1, so as to generate airflow blowing to the electronic component CM1.

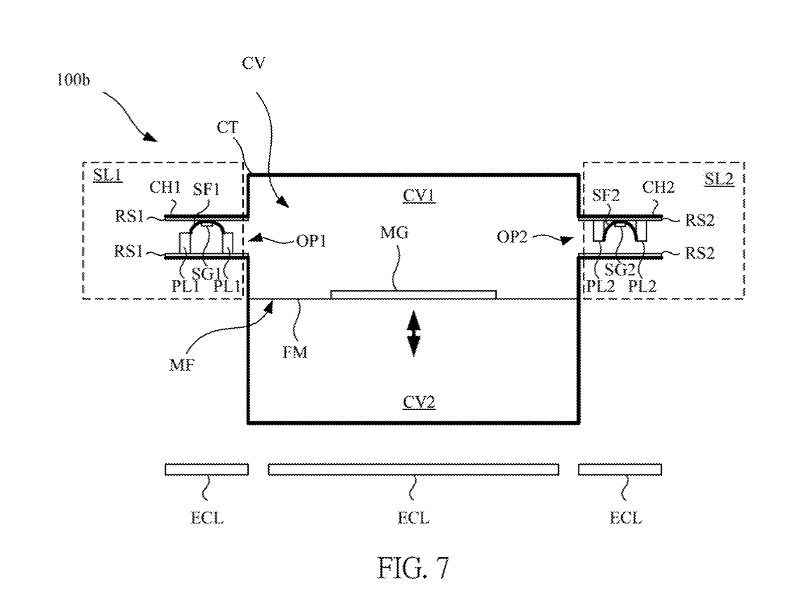

FIG. 7 is a schematic diagram of an airflow generating device 100b according to another embodiment of the present disclosure. In this embodiment, the airflow generating device 100b includes a container CT, a first air switch SL1, a second air switch SL2, and an oscillating element MF. In this embodiment, the airflow generating device 100b is substantially identical to the airflow generating device 100a. Thus, a description of many aspects in this regard will not be repeated.

In one embodiment, the first air switch SL1 is disposed at the first opening OP1, configured to open or close the first opening OP1. The second air switch SL2 is disposed at the second opening OP2, configured to open or close the second opening OP2.

In one embodiment, the first air switch SL1 and the second air switch SL2 respectively open or close the first opening OP1 and the second opening OP2 according to the AC magnetic field generated by the one or more external power providing coils ECL.

In one embodiment, the first air switch SL1 and the second air switch SL2 do not close the first opening OP1 and the second opening OP2 concurrently. When the second air switch SL2 closes the second opening OP2, the first air switch SL1 opens the first opening OP1, and when the first air switch SL1 closes the first opening OP1, the second air switch SL2 opens the second opening OP2.

In one embodiment, the first air switch SL1 open or close the first opening OP1 corresponding to the first space CV1 is being compressed or expanded. In one embodiment, the second air switch SL2 open or close the second opening OP2 corresponding to the first space CV1 is being compressed or expanded.

In one embodiment, the first air switch SL1 includes a switching film SF1, a magnetic element SG1, pillars PL1, and a channel CH1. In one embodiment, the switching film SF1, the magnetic element SG1, and the pillars PL1 are disposed within the channel CH1. In one embodiment, the pillars PL1 are disposed at the bottom side of the channel CH1. Two ends of the switching film SF1 are separately disposed at the pillars PL1. The magnetic element SG1 is disposed on the switching film SF1. In one embodiment, the switching film SF1 may motion according to the AC magnetic field generated by one or more external power providing coils ECL, so as to open or close the first opening OP1. For example, the switching film SF1 may bend upward according, to the AC magnetic field to close the first opening OP1, or bend downward according to the AC magnetic field to open the first opening OP1. It should be noted that the pillars PL1 can be disposed at the top side or the bottom side of the channel CH1 on a basis of actual requirements, and the present disclosure is not limited by this embodiment. It should be noted that, in one embodiment, there may be multiple magnetic elements SG1 disposed on the switching film SF1, and the present disclosure is not limited by the embodiment described above. Additionally, in one embodiment, the switching film SF1 and the magnetic element SG1 can be integrated as a magnetic switching film, and the present disclosure is not limited by the embodiment described above.

In one embodiment, the first air switch SL1 further includes a resilience cushion RS1 disposed between the channel CH1 and the switching film SF1. In one embodiment, the resilience cushion RS1 can be disposed at the top side and/or the bottom side of the channel CH1. Under a condition that the magnetic element SG1 open or close the first opening OP1, the switching film SF1 is against the channel CH1 with the resilience cushion RS1 intervened, so as to avoid abrasions of the magnetic element SG1 and the channel CH1.

In one embodiment, the second air switch SL2 includes a switching film SF2, a magnetic element SG2, pillars PL2, and a channel CH2. In one embodiment, the switching film SF2, the magnetic element SG2, and the pillars PL2 are disposed within the channel CH2. In one embodiment, the pillars PL2 are disposed at the top side of the channel CH2. Two ends of the switching film SF2 are separately disposed at the pillars PL2. The magnetic element SG2 is disposed on the switching film SF2. In one embodiment the switching film SF2 may mot o n according to the AC magnetic field generated by one or more external power providing coils ECL, so as to open or close the second opening OP2. For example, the switching film SF2 may bend upward according to the AC magnetic field to open the second opening OP2, or bend downward according to the AC magnetic field to close the second opening OP2. It should be noted that the pillars PL2 can be disposed at the top side or the bottom side of the channel CH2 on a basis of actual requirements, and the present disclosure is not limited by this embodiment. It should be noted that, in one embodiment, there may be multiple magnetic elements SG2 disposed on the switching film SF2 and, the present disclosure is not limited by the embodiment described above. Additionally, in one embodiment, the switching film SF2 and the magnetic element SG2 can be integrated as a magnetic switching film and the present disclosure is not limited by the embodiment described above.

In one embodiment, the second a switch SL2 further includes a resilience cushion RS2 disposed between the channel CH2 and the switching film SF2. In one embodiment, the resilience cushion RS2 can be disposed at the top side and/or the bottom side of the channel CH2. Under a condition that the magnetic element SG2 open or close the second opening OP2, the switching film SF2 is against the channel CH2 with the resilience cushion RS2 intervened, so as to avoid abrasions of the magnetic element SG2 and the channel CH2.

To allow the disclosure to be more fully understood, an operative example is described in the paragraphs below, but the present disclosure is not limited to the example below:

In this operative embodiment, the N poles of the oscillating element MF and the magnetic elements SG1, SG2 are facing toward the one or more external power providing coils ECL (e.g., facing downward), and the S poles of the oscillating element MF and the magnetic elements SG1, SG2 are facing opposite to the one or more external power providing coils ECL (e.g., facing upward). During a period that the N pole of the magnetic field generated by the one or more external power providing coils ECL is directed toward the oscillating element MF and the magnetic elements SG1, SG2 (e.g., directed upward), and the S pole of the magnetic field is directed opposite to oscillating element MF and the magnetic elements SG1, SG2 (e.g., directed downward), a repulsive force is generated from the one or more external power providing coils ECL to the oscillating element MF and the magnetic elements SG1, SG2. The magnetic elements SG1, SG2 motion toward a direction opposite to the one or more external power providing coils ECL (e.g., toward an up direction) according to the repulsive force, so as to make the switching films SF1, SF2 bend toward a direction opposite to the one or more external power providing coils ECL (e.g., toward an up direction), to close the fiat opening OP1 and open the second opening OP2. In addition, the oscillating element MF is changing its shape toward a direction opposite to the one or more external power providing coils ECL (e.g. changing the shape upward) according to the repulsive force, so as to make the first spacing CV1 is being compressed and the second spacing CV2 is being expanded. At this time, the airflow generating device 100b blows air by using the second opening OP2.

During a period that the S pole of the magnetic field generated by the one or more external power providing coils ECL is directed toward the oscillating element MF and the magnetic elements SG1, SG2 (e.g. directed upward), and the N pole of the magnetic field is directed opposite to oscillating element MF and the magnetic elements SG1, SG2 (e.g., directed downward), an attractive force is generated from the one or more external power providing coils ECL to the oscillating element MF and the magnetic elements SG1, SG2. The magnetic elements SG1, SG2 motion toward the one or more external power providing coils ECL (e.g., toward an down direction) according to the attractive force, so as to make the switching films SF1, SF2 bend toward the one or more external power providing coils ECL (e.g., toward an down direction), to open the first opening OP1 and close the second opening OP2. In addition, the oscillating element MF is changing its shape toward the one or more external power providing coils ECL (e.g., changing the shape upward) according to the attractive force, so as to make the first spacing CV1 is being expanded and the second spacing CV2 is being compressed. At this time, the airflow generating device 100b sucks air by using the first opening OP1.

Through the operations described above, the airflow generating device 100b can suck air by using the first opening OP1 and blow air by using the opened second opening OP2. In such a manner, airflow with a fixed direction can be generated, and it can avoid hot air to be sucked back into the airflow generating device 100b to decrease the heat dissipation efficiency.

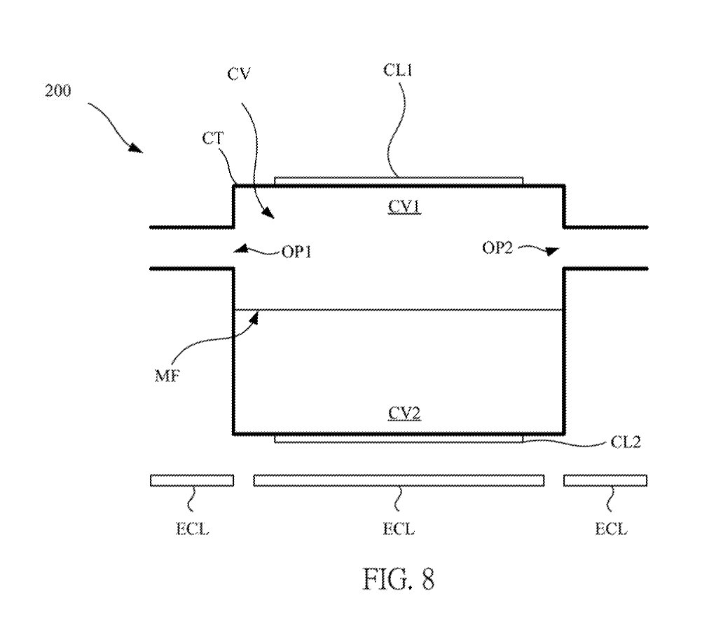

FIG. 8 is a schematic diagram of an airflow generating device 200 according to another embodiment of the present disclosure. In this embodiment, the airflow generating device 200 includes a container CT, a first air switch SL1, a second air switch SL2, an oscillating element MF, and coils CL1, CL2. In this embodiment, the airflow generating device 200 is substantially identical to the airflow generating device 100. Thus, a description of many aspects in this regard will not be repeated.

In one embodiment, the oscillating element MF may include a piezoelectric film. In one embodiment, the oscillating element MF can oscillate according to variations of an electronic signal applied thereto. For example, when a current with a first flowing direction is provided to the oscillating element MF, the oscillating element MF changes the shape thereof toward a first direction. When a current with a second flowing direction (opposite to the first flowing direction) is provided to the oscillating element MF, the oscillating element MF changes the shape thereof toward a second direction (opposite to the first direction).

In one embodiment, the coils CL1, CL2 are disposed at locations that can easily sense the AC magnetic field generated by the one or more external power providing coils ECL. In one embodiment the coils CL1, CL2 are disposed on the container CT. In one embodiment, the coil CL1 is disposed at one side (e.g., the bottom side) of the container CT, and the coil CL2 is disposed at an opposite side (e.g., the top side) of the container CT. In one embodiment, the coils CL1, CL2 may be separately realized by one or more of a planar coil, a coil with a solid form, or a PCB coil, but another realization manner is within the contemplated scope of the present disclosure. It should be noted that two coils CL1, CL2 are taken as an example in this embodiment, but another amount of the coils (e.g., one or more than two) is within the contemplated scope of the present disclosure. Moreover, in this embodiment, the coils CL1, CL2 are disposed outside the container CT. However, the coils CL1, CL2 may also be separately disposed inside and/or outside the container CT. Furthermore, the coils CL1, CL2 can be disposed at any appropriated locations of the airflow generating device 200 or apart from the airflow generating device 200 on a basis of actual requirements, and the present disclosure is not limited by this embodiment.

In one embodiment, the coils CL1, CL2 are configured to generate an induced magnetic field and an induced AC current corresponding to the AC magnetic field generated by the one or more external power providing coils ECL. The piezoelectric film of the oscillating element MF can receive this induced AC current, and oscillate in the container CT according to this induced AC current.

For example, the induced AC current may include a sensing current with a first flowing direction and a sensing current with a second flowing direction (opposite to the first flowing direction). When the sensing current with the first flowing direction is provided to the oscillating element MF, the oscillating element MF changing its shape toward a first direction (e.g., toward an up direction). At this time, the first spacing CV1 is being compressed arid the second spacing CV2 is being expanded, so that the airflow generating device 200 blows air by using the first opening OP1 and the second opening OP2.

When the sensing current with the second flowing direction is provided to the oscillating element MF, the oscillating element MF changing its shape toward a second direction (e.g., toward a down direction). At this time, the first spacing CV1 is being expanded and the second spacing CV2 is being compressed, so that the airflow generating device 200 sucks air by using the first opening OP1 and the second opening OP2.

With such a configuration, a wireless driving airflow generating device 200 can be realized. In addition, since the airflow generating device 200 can receive the power from the one or more external power providing coils ECL without using electronic elements rectifiers and transformers), so that power loss can be decreased.

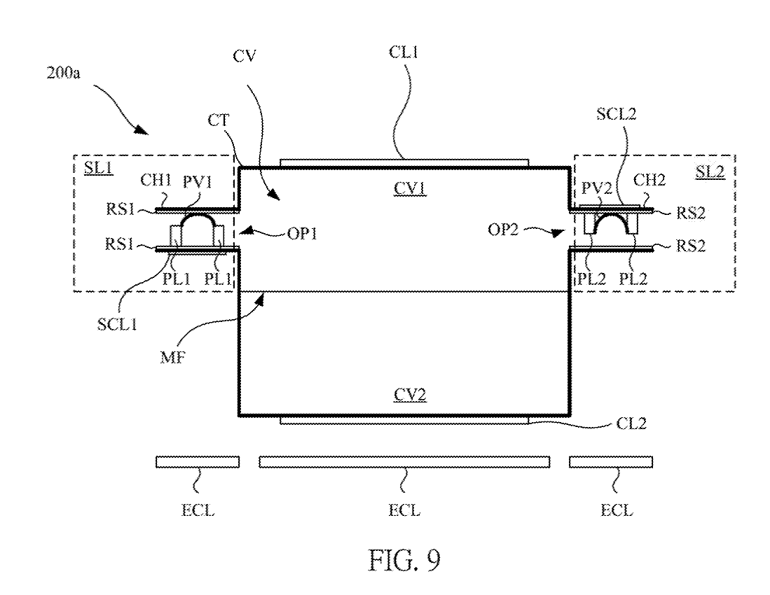

FIG. 9 is a schematic diagram of an ow generating device 200a according to another embodiment of the present disclosure. In this embodiment, the airflow generating device 200a includes a container CT, a first air switch SL1, a second air switch SL2, an oscillating element MF, coils CL1, CL2, and switching coils SCL1, SCL2. In this embodiment, the container CT, the oscillating element MF, and the coils CL1, CL2 of the airflow generating device 200a are substantially identical to the container CT, the oscillating element MF and the coils CL1, CL2 of the airflow generating device 200. Thus, a description of many aspects in this regard will not be repeated.

In addition, in this embodiment, the switching coils SCL1, SCL2, the first air switch SL1, and the second air switch SL2 of the airflow generating device 200a are substantially identical to the switching coils SCL1, SCL2, the first air switch SL1, and the second air switch SL2 of the airflow generating device 100a. Thus, a description of many aspects in this regard will not be repeated.

It should be noted that, in some embodiments, the coils CL1, CL2 and the switching coils SCL1, SCL2 can be integrated into one or more coils, and the present disclosure is not limited to the embodiment illustrated in FIG. 9.

To allow the disclosure to be more fully understood, an operative example relating to operations of the airflow generating device 200a is described in the paragraphs below, but the present disclosure is not limited to the example below.

In this operative example, when the coils CL1, CL2 provide the sensing current with the first flowing direction to the oscillating element MF according to the AC magnetic field generated by the one or more external power providing coils ECL, the oscillating element MF is changing the shape thereof toward a first direction (e.g., toward an up direction), so that the first spacing CV1 is being compressed and the second spacing CV2 is being expanded. In this period, the switching coils SCL1, SCL2 generate the first switching current ISN1, so as to make the piezoelectric sheet PV1 bend toward a first direction (e.g., toward an up direction) according to the first switching current ISN1 to close the first opening OP1, and make the piezoelectric sheet PV2 bend toward the first direction (e.g., toward an up direction) according to the first switching current ISN1 to open the second opening OP2. Therefore, the airflow generating device 100a blows air by using the opened second opening OP2.

On the other hand, when the coils CL1, CL2 provide the sensing current with the second flowing direction to the oscillating element MF according to the AC magnetic field generated by the one or more external power providing coils ECL, the oscillating element MF is changing the shape thereof toward a second direction (e.g., toward a down direction), so that the first spacing CV1 is being expanded and the second spacing CV2 is being compressed. In this period, the switching coils SCL1, SCL2 generate the second switching current ISN2, so as to make the piezoelectric sheet PV1 bend toward a second direction (e.g., toward a down direction) according to the second switching current ISN2 to open the first opening OP1, and make the piezoelectric sheet PV2 bend toward the second direction (e.g., toward a down direction) according to the second switching current ISN2 to close the second opening OP2. Therefore, the airflow generating device 200a sucks air by using the opened first opening OP1.

It should be noted that, in different embodiments, the directions of the oscillating element MF, the piezoelectric sheet PV1, and the piezoelectric sheet PV2 change their shapes toward or bend toward can be different from each other, and the present disclosure is not limited by the embodiment described above.

Moreover, in one embodiment, the airflow generating device 200a may also include a switching element SWC. The switching element SWC is electrically connected between the switching coils SCL1, SCL2, coils CL1, CL2, the first air switch SL1, and the second air switch SL2, configured to selectively change current paths of the switching currents ISN1, ISN2. In one embodiment, the switching element SWC is configured to selectively change directions of the switching currents ISN1 ISN2 passing through the first air switch SL1 and the second air switch SL2. Details of the switching element SWC and operations and applications of the airflow generating device 200a having the switching element SWC can be ascertained with reference to the paragraphs above, and a description in this regard will not be repeated.

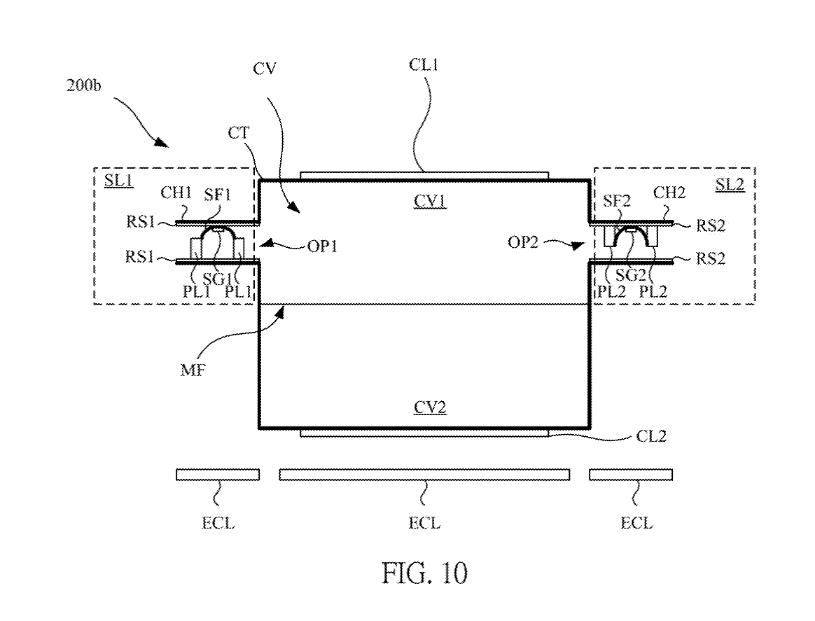

FIG. 10 is a schematic diagram of an airflow generating device 200b according to another embodiment of the present disclosure. In this embodiment, the airflow generating device 200b includes a container CT, a first air switch SL1, a second air switch SL2, an oscillating element MF, and coils CL1, CL2. In this embodiment, the container CT, the oscillating element MF, and the coils CL1, CL2 of the airflow generating device 200b are substantially identical to the container CT, the oscillating element MF, and the coils CL1, CL2 of the airflow generating device 200. Thus, a description of many aspects in this regard will not be repeated.

Moreover, in this embodiment the first air switch SL1 and the second air switch SL2 of the airflow generating device 200b are substantially identical to the first air switch SL1 and the second air switch SL2 of the airflow generating device 100b. Thus, a description of many aspects in this regard will not be repeated.

To allow the disclosure to be more fully understood, an operative example relating to operations of the airflow generating device 200b is described in the paragraphs below, but the present disclosure is not limited to the example below.

In this operative example, the N poles of the magnetic elements SG1, SG2 are facing toward the one or more external power providing coils ECL (e.g., facing downward), and the S poles of the oscillating element MF and the magnetic elements SG1, SG2 are facing opposite to the one or more external power providing coils ECL (e.g., facing upward). When the coils CL1, CL2 provide the sensing current with the first flowing direction to the oscillating element MF according to the AC magnetic field generated by the one or more external power providing coils ECL, the oscillating element MF is changing the shape thereof toward a first direction (e.g., toward an up direction), so that the first spacing CV1 is being compressed and the second spacing CV2 is being expanded. At this time, a repulsive force is generated from the one or more external power providing coils ECL to the magnetic elements SG1 SG2. The magnetic elements SG1, SG2 motion toward a direction opposite to the one or more external power providing coils ECL (e.g., toward an up direction) according to the repulsive force, so as to make the switching films SF1, SF2 bend toward a direction opposite to the one err more external power providing coils ECL (e.g., toward an up direction), to close the first opening OP1 and open the second opening OP2. Therefore, the airflow generating device 200b blows air by using the second opening OP2.

When the coils CL1, CL2 provide the sensing current with the second flowing direction to the oscillating element MF according to the AC magnetic field generated by the one or mora external power providing coils ECL, the oscillating element MF is changing the shape thereof toward a second direction (e.g., toward a down direction), so that the first spacing CV1 is being expanded and the second spacing CV2 is being compressed. At this time, an attractive force is generated from the one or more external power providing coils ECL to the magnetic elements SG1, SG2. The magnetic elements SG1, SG2 motion toward the one or more external power providing coils ECL (e.g., toward a down direction) according to the attractive force, so as to make the switching films SF1, SF2 bend toward the one or more external power providing coils ECL (e.g., toward a down direction), to open the first opening OP1 and close the second opening OP2. Therefore, the airflow generating device 200b sucks air by using the second opening OP2.

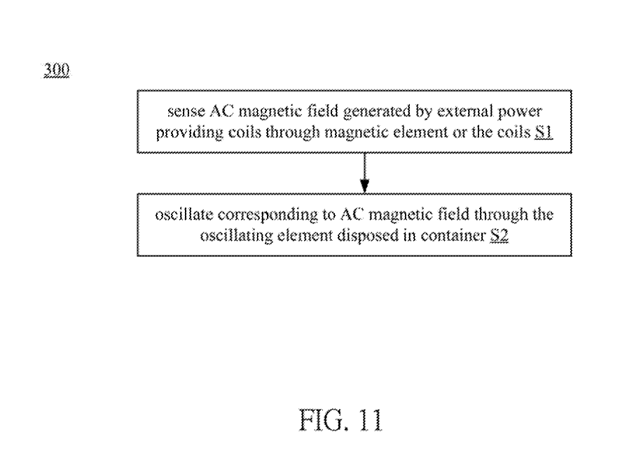

Details of the present disclosure are described in the paragraphs below with reference to an airflow generating method in FIG. 11. However, the present disclosure is not limited to the embodiment below.

It should be noted that the airflow generating method can be applied to an airflow generating device having a structure that is the same as or similar to the structure of the mobile device 100 shown in FIG. 1 or the mobile device 200 shown in FIG. 8. To simplify the description below, the embodiment shown in FIG. 1 or FIG. 8 will be used as an example to describe the airflow generating method according to an embodiment of the present disclosure. However, the present disclosure is not limited to application to the embodiment shown in FIG. 1 or FIG. 8. The airflow generating method can also be applied to the airflow generating devices 100a, 100b, 200a, 200b.

In addition, it should be noted that in the operations of the following airflow generating method, no particular sequence is required unless otherwise specified. Moreover, the following operations also may be performed simultaneously or the execution times thereof may at least partially overlap.

Furthermore, the operations of the following airflow generating method may be added to, replaced, and/or eliminated as appropriate, in accordance with various embodiments of the present disclosure.

Reference is made to FIG. 11. The airflow generating method 300 includes the operations below.

In operation S1, the airflow generating device 100 or the airflow generating device 200 senses an AC magnetic field generated by the one or more external power providing coils ECL through the magnetic element MG or the coils CL1, CL2.

In operation S2, the airflow generating device 100 or the airflow generating device 200 oscillates corresponding to the AC magnetic field through the oscillating element MF disposed in the container CT.

It should be noted that details of the operations described above can be ascertained with reference to the embodiments described above, and a description in this regard will not be repeated herein.

Through the operations described above, an airflow generating device can receive power without using electronic elements (e.g., rectifiers and transformers), so that power loss can be decreased.

Although the present disclosure has been described in considerable detail with reference to certain embodiments thereof, other embodiments are possible. Therefore, the scope of the appended claims should not be limited to the description of the embodiments contained herein.

What is claimed is:

1. An airflow generating device comprising:
a container having at least one opening; and
an oscillating element disposed in the container, separates an inner space of the container into a first space and a second space, wherein the first space and the second space are isolated from each other, and the opening is connected to one of the first space and the second space;
wherein the oscillating element is configured to oscillate corresponding o an AC magnetic field generated by one or more external power providing coils.

2. The airflow generating device as claimed in claim 1 further comprising:
one or more coils configured to generate an AC current and drive the oscillating element to oscillate according to the AC current.

3. The airflow generating device as claimed in claim 2, wherein the oscillating element comprises a piezoelectric sheet, the piezoelectric sheet is configured to receive the AC current and oscillate in the container according to the AC current.

4. The airflow generating device as claimed in claim 1, wherein the oscillating element is a magnetic oscillating element the AC magnetic field applies a magnetic force to the magnetic oscillating element, so as to make the magnetic oscillating element oscillate according to the magnetic force.

5. The airflow generating device as claimed in claim 1, wherein the at least one opening comprises a first opening and a second opening, and the airflow generating device further comprises:
a first air switch configured to open or close the first opening corresponding to the AC magnetic field; and
a second air switch configured to open or close the second opening corresponding to the AC magnetic field;
wherein under a condition that the first air switch closes the first opening, the second air switch opens the second opening, and under a condition that the second air switch closes the second opening, the first air switch opens the first opening.

6. The airflow generating device as claimed in claim 5, wherein the first air switch comprises a first magnetic element, and the first magnetic element motions corresponding to the AC magnetic field to open or close the first opening.

7. The airflow generating device as claimed in claim 5 further comprising:
one or more switching coils configured to generate at least one switching current corresponding to the AC magnetic field and drive the first air switch open or close the first opening by using the switching current.

8. The airflow generating device as claimed in claim 7 further comprising:
a switching component electrically connected between the one or more switching coils, the first air switch, and the second air switch;
wherein when the switching component is in a first switching state, when the oscillating element is changing a shape thereof toward a first direction corresponding to the AC magnetic field, the one or more switching coils generate a first switching current corresponding to the AC magnetic field, so as to make the first air switch close the first opening according to the first switching current, and make the second air switch open the second opening according to the first switching current;
and when the oscillating element is changing the shape thereof toward a second direction corresponding to the AC magnetic field, the one or more switching coils generate a second switching current corresponding to the AC magnetic field, so as to make the first air switch open the first opening according to the second switching current, and make the second air switch close the second opening according to the second switching current.

9. The airflow generating device as claimed in claim 8, wherein when the switching component is in a second switching state, when the oscillating element is changing the shape thereof toward the first direction corresponding to the AC magnetic field, the one or more switching coils generate the first switching current corresponding to the AC magnetic field, so as to make the first air switch open the first opening according to the first switching current, and make the second air switch close the second opening according to the first switching current;
and when the oscillating element is changing the shape thereof toward the second direction corresponding to the AC magnetic field, the one or more switching coils generate the second switching current corresponding to the AC magnetic field, so as to make the first air switch close the first opening according to the second switching current, and make the second air switch open the second opening according to the second switching current.

10. An airflow generating method comprising:
sensing, through a magnetic element or one or more coils, an AC magnetic field generated by one or more external power providing coils; and
oscillating, through an oscillating element disposed in a container, corresponding to the AC magnetic field;
wherein the oscillating element separates an inner space of the container into a first space and a second space, the first space and the second space are isolated from each other, and at least one opening of the container is connected to one of the first space and the second space.
